(19) United States
(12) Patent Application Publication
(10) Pub. No.: US 2012/0002354 A1
(43) Pub. Date: Jan. 5, 2012

(54) SELF-SERVICE TERMINAL

(75) Inventors: CHIH-KUN SHIH, Santa Clara, CA (US); YANG-JIE LUO, Shenzhen City (CN); WAN-CHENG LUO, Shenzhen City (CN); SI-LONG LI, Shenzhen City (CN); XIANG-XIONG XIAO, Shenzhen City (CN); JIE PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/970,056

(22) Filed: Dec. 16, 2010

(30) Foreign Application Priority Data
Jul. 2, 2010 (CN) 201010216228.6

(51) Int. Cl. H05K 7/00

(52) U.S. Cl. 361/679.01

(57) ABSTRACT

A self-service terminal includes a control portion and a slide panel. The control portion includes a user interface cover and a maintenance operation portion. The user interface cover is pivotably mounted on the control portion, and rotates on the control portion between a first position and a second position. In the first position, the user interface cover shields the maintenance operation portion to make the maintenance operation portion inaccessible. In the second position, the user interface cover does not shield the maintenance operation portion and the maintenance operation portion is accessible. The slide panel is slidably mounted in the maintenance operation portion. A keyboard and a mouse are mounted on the slide panel. The slide panel hangs over the maintenance operation portion when the user interface cover is in the second position, and is retracted in the maintenance operation portion when the user interface cover is in the first position.

### BACKGROUND

1. Technical Field

The present disclosure relates to electronic devices, more particularly a self-service terminal.

2. Description of Related Art

Self-service terminals are developed for bank customers to process a lot of daily financial transactions, such as depositing currency, withdrawing currency, and inquiring account information. After new self-service terminals come into use, new software often needs to be updated to add new services or to improve security. Old self-service terminals tend to break down easily. Therefore, maintenance is important for the self-service terminals no matter if they are new or old. Usually, keyboards and mice are required for the maintenance work.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a self-service terminal in accordance with an embodiment.

FIG. 2 is an isometric and exploded view of a control portion of the self-service terminal of FIG. 1.

FIG. 3 is an isometric and assembly view of the control portion of FIG. 2.

FIG. 4 is an isometric view of the self-service terminal of FIG. 1 showing a sliding plate hang over the control portion.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

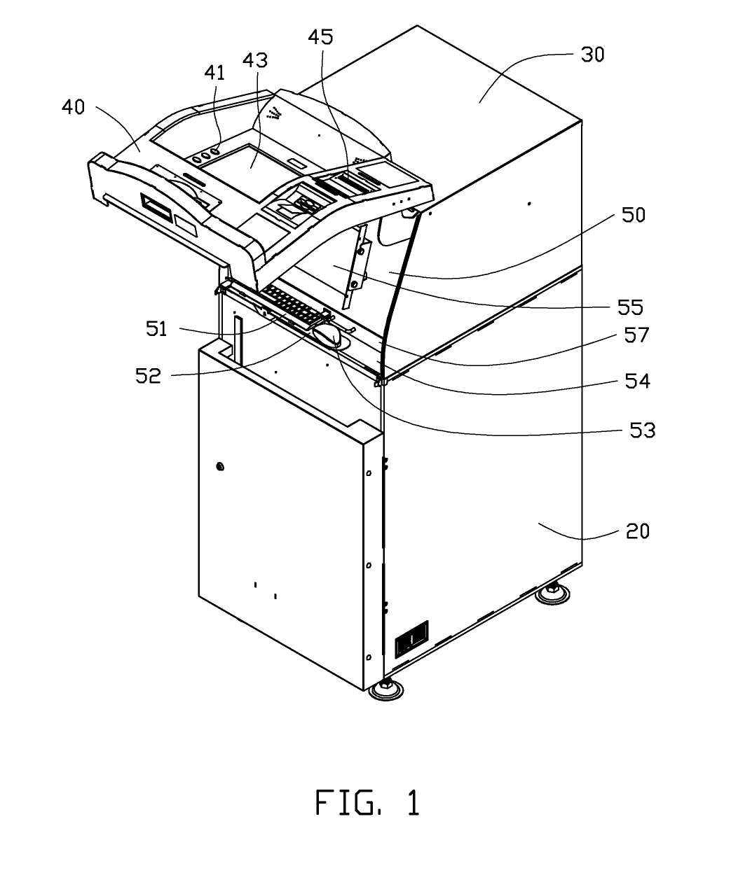

Referring to FIG. 1, a self-service terminal in accordance with an embodiment includes a rack 20. A control portion 30 is located on an upper part of the rack 20. The control portion 30 includes an outside user interface cover 40 and an inner maintenance operation portion 50. The user interface cover 40 is pivotally mounted on the control portion. When the self-service terminal is in a working state, the user interface cover 40 rotates to cover the maintenance operation portion 50 to keep the maintenance operation portion 50 inaccessible. When the self-service terminal is in a maintenance state, the user interface cover 40 rotates to expose the maintenance operation portion 50 for excess.

The user interface cover 40 is equipped with a number of buttons 41, an outside screen 43, and a number of slots 45. The buttons 41 are used by users to input instructions. The outside screen 43 is used to show information to the users. The plurality of number of slots 45 is used to receive cards, or output cash.

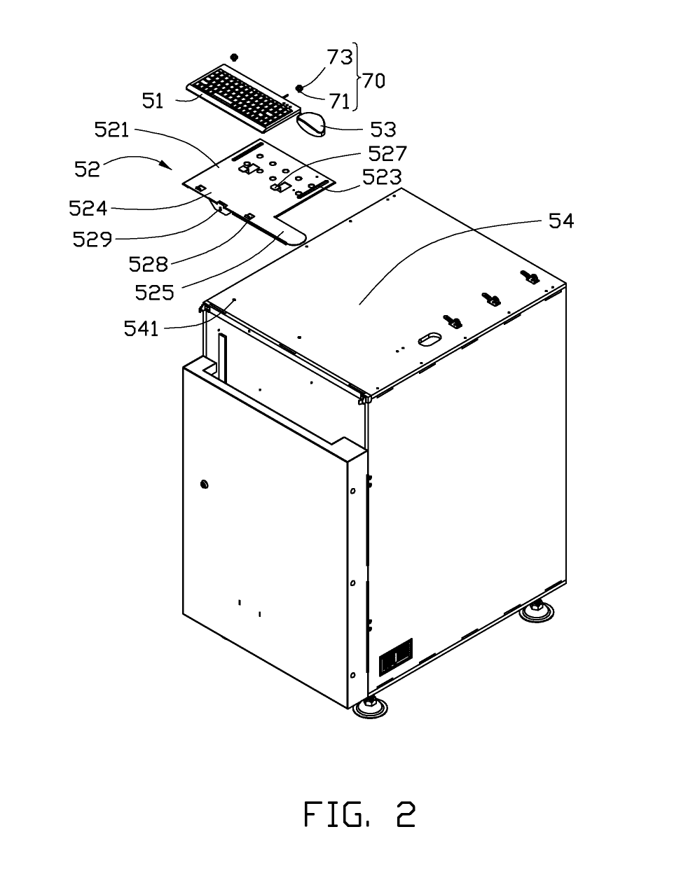

Referring to FIGS. 1 and 2, the maintenance operation portion 50 includes a keyboard 51, a mouse 53, a slide panel 52, a support board 54, an inside screen 55, and a sustain plate 57. The sustain plate 57 is located parallel to and above the support board 54. The inside screen 55 is secured on the sustain plate 57 for showing information to maintainers. The support board 54 defines a pair of mount holes 541.

The slide panel 52 includes a rectangular main portion 521 and an extended portion 525 extending from the main portion 521. A pair of clasps 527 is located on the main portion 521. A pair of restricting pieces 528 is located adjacent a front edge of the main portion 521. A keyboard support portion 524 is defined between the pair of clasps 527 and the pair of restricting pieces 528. A pair of grooves 523 is defined in the main portion 521. A central portion of the front edge of the main portion 521 extends perpendicularly and downwardly to form a stopper 529.

A pair of screws 70 is configured to be secured in the pair of mounting holes 541 of the support board 54. Each screw 70 includes a thin pole portion 71 and a thick head portion 73. A diameter of the pole portion 71 is smaller than a width of the groove 523, and can slide in the groove 523. A diameter of the head portion 73 is larger than a width of the groove 523.

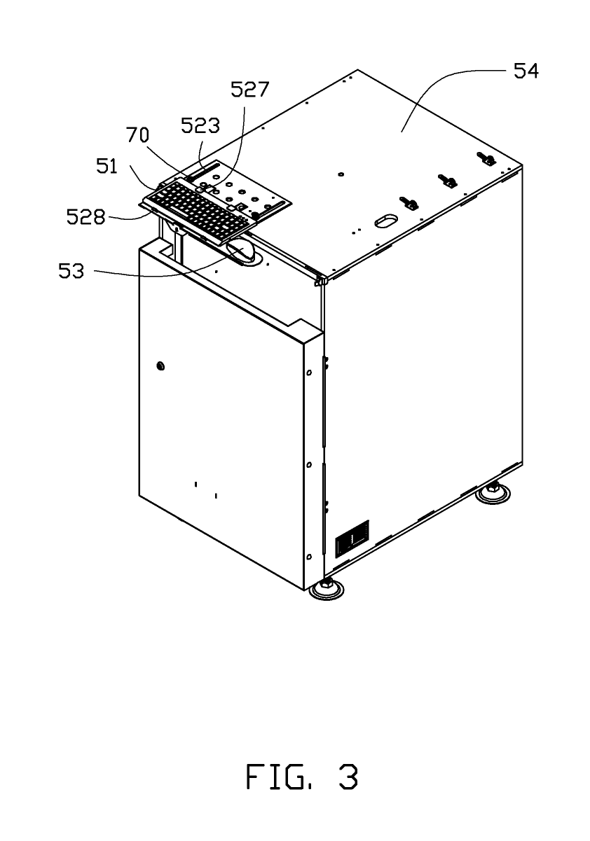

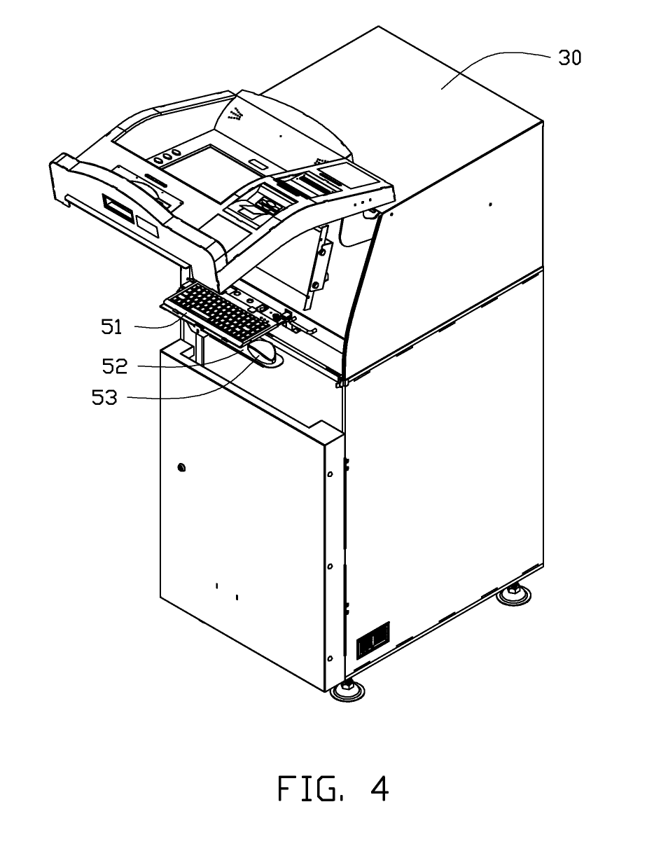

Referring to FIGS. 1 to 4, in assembly of the self-service terminal, the slide panel 52 is placed on the support board 54 with the grooves 523 in alignment with the mounting holes 541. The pole portion 71 of each screw 70 inserts through the groove 523, and is secured in corresponding mounting hole 541. Therefore, the slide panel 52 is slidably mounted on the support board 54. The keyboard 51 is positioned on the keyboard support portion 524 of the slide panel 52. A front edge of the keyboard 51 resists against the restricting pieces 528. A rear edge of the keyboard 51 is fastened by the clasps 527. The mouse 53 is then positioned on the extended portion 525 of the slide panel 52.

When maintenance workers need to use the keyboard 51 and mouse 53 to service the self-service terminal, the slide panel 52 slides on the support board 54 to hang over the support board 54. Therefore, it is convenient to use the keyboard 51 and mouse 53. When the maintenance workers do not need to service the self-service terminal, the slide panel 52 slides on the support board 54 until the stopper 529 resists a front edge of the support board 54. At this position, the slide panel 52 is retracted in the support board 54.

Therefore, the self-service terminal is equipped with the keyboard 51 and mouse 53 for convenient maintenance of the self-service terminal

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A self-service terminal, comprising:
a control portion comprising a user interface cover and a maintenance operation portion, the user interface cover pivotably mounted on the control portion, wherein the user interface cover is configured to rotate on the control portion between a first position and a second position; in the first position, the user interface cover shields the maintenance operation portion to make the maintenance operation portion inaccessible; in the second position, the user interface cover does not shield the maintenance operation and the maintenance operation portion is accessible; and
a slide panel slidably mounted in the maintenance operation portion; and a keyboard and a mouse mounted on the slide panel; wherein the slide panel is configured to hang over the maintenance operation portion when the user interface cover is in the second position, and configured to be retracted in the maintenance operation portion when the user interface cover is in the first position.

2. The self-service terminal of claim 1, wherein the maintenance operation portion comprises a support board, and the slide panel is slidably mounted on the support board.

3. The self-service terminal of claim 2, wherein the slide panel defines a groove, a screw is mounted on the support board, and the screw is located in the groove, and is configured to slide in the groove.

4. The self-service terminal of claim 3, wherein the support board defines a mounting hole in which the screw is mounted, the screw comprises a thin pole portion and a thick head portion, a diameter of the thin pole portion is smaller than a width of the groove, a diameter of the thick head portion is larger than a width of the groove; and the thin pole portion is located in the groove, and the thick head portion is located out of the groove to retain the thin pole portion in the groove.

5. The self-service terminal of claim 1, wherein the slide panel comprises a main portion and an extended portion coupled with the main portion, the keyboard is located on the main portion, and the mouse is located on the extended portion.

6. The self-service terminal of claim 5, wherein a pair of clasps is located on the main portion, a pair of restricting pieces is located adjacent a front edge of the main portion, a front edge of the keyboard abuts the pair of restricting pieces, and a rear edge of the keyboard is gripped by the pair of clasps when the user interface cover is in the first position.

7. The self-service terminal of claim 6, wherein a stopper is perpendicularly coupled with the front edge of the main portion, and the stopper is configured to abut an edge of the support board when the user interface cover is in the first position.

8. A self-service terminal, comprising:
a control portion comprising a user interface cover and a maintenance operation portion, the user interface cover comprising a first screen, the maintenance operation portion comprising a second screen, the user interface cover pivotably mounted on the control portion, wherein the user interface cover is configured to rotate on the control portion between a first position and a second position; in the first position, the first screen shields the second screen; in the second position, the first screen does not shield the second screen, and the second screen is exposed to outside; and
a slide panel slidably mounted in the maintenance operation portion, the slide panel located below the second screen, and a keyboard and a mouse mounted on the slide panel; wherein the slide panel is configured to hang over the maintenance operation portion when the user interface cover is in the second position, and configured to be retracted in the maintenance operation portion when the user interface cover is in the first position.

9. The self-service terminal of claim 8, wherein the maintenance operation portion comprises a support board, and the slide panel is slidably mounted on the support board.

10. The self-service terminal of claim 9, wherein the slide panel defines a groove, a screw is mounted on the support board, and the screw is located in the groove, and configured to slide in the groove.

11. The self-service terminal of claim 10, wherein the support board defines a mounting hole in which the screw is mounted, the screw comprises a thin pole portion and a thick head portion, a diameter of the thin pole portion is smaller than a width of the groove, a diameter of the thick head portion is larger than a width of the groove; and the thin pole portion is located in the groove, and the thick head portion is located out of the groove to retain the thin pole portion in the groove.

12. The self-service terminal of claim 8, wherein the slide panel comprises a main portion and an extended portion coupled with the main portion, the keyboard is located placed on the main portion, and the mouse is located on the extended portion.

13. The self-service terminal of claim 12, wherein a pair of clasps is located on the main portion, a pair of restricting pieces is located adjacent a front edge of the main portion, a front edge of the keyboard abuts the pair of restricting pieces, and a rear edge of the keyboard is gripped by the pair of clasps when the user interface cover is in the first position.

14. The self-service terminal of claim 13, wherein a stopper is perpendicularly coupled with the front edge of the main portion, and the stopper is configured to abut an edge of the support board when the user interface cover is in the first position.
